(19) United States
(12) Patent Application Publication
(10) Pub. No.: US 2004/0245329 A1
(43) Pub. Date: Dec. 9, 2004

(54) VIPER ATX COMPUTER CHASSIS

(75) Inventor: Edward Huang, Walnut, CA (US)

Correspondence Address: MGE COMPANY, 20621 E. VALLEY BLVD. #A, WALNUT, CA, 91789, US

(73) Assignee: MGE Company, Walnut, CA (US)

(21) Appl. No.: 10/710,921

(22) Filed: Aug. 12, 2004

(51) Int. Cl. G06F 17/00; G06F 1/16; H05K 5/00; H05K 7/00; A47B 81/00; A47B 97/00

(52) U.S. Cl. 235/375; 361/683; 312/223.2

(57) ABSTRACT

The VIPER ATX Computer Chassis was developed for the sole purpose of increasing overall system performance through the use of advanced cooling chassis designs and the dissipation of heat. Its advanced LCD display and overall features increase its value and necessity in this performance driven computer market.

### SUMMARY OF INVENTION

The VIPER computer chassis is designed to provide unlimited aesthetic enjoyment to the owner. It is aggressively styled for computer gaming enthusiasts while providing an abundant source of expandability and usage with it's full drive bay chassis. The VIPER holds many new features that will keep it in the fashionable trend of computer cases.

### BRIEF DESCRIPTION OF DRAWINGS

FIG. 1 displays the advanced VIPER LCD Display, MGE is the first to develop a lighted, high resolution logo or ‘emblem’ that can be displayed within the LCD panel as well as blink on and off.

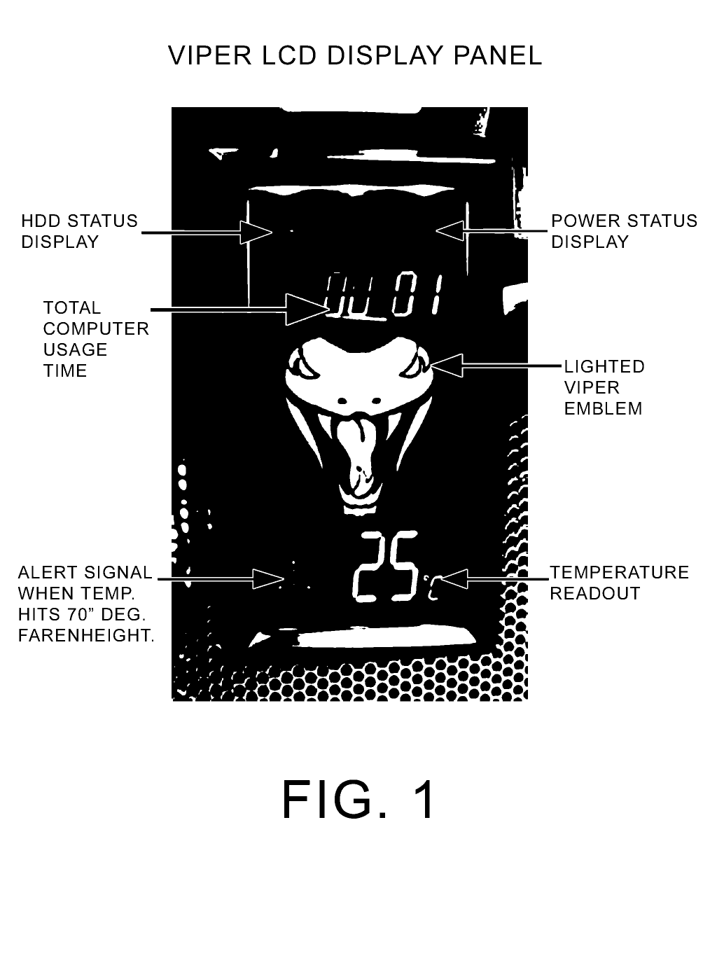

FIG. 2 demonstrates VIPER's Centralized Control Center allows a systematically placed I/O port hub along with Power and Reset buttons.

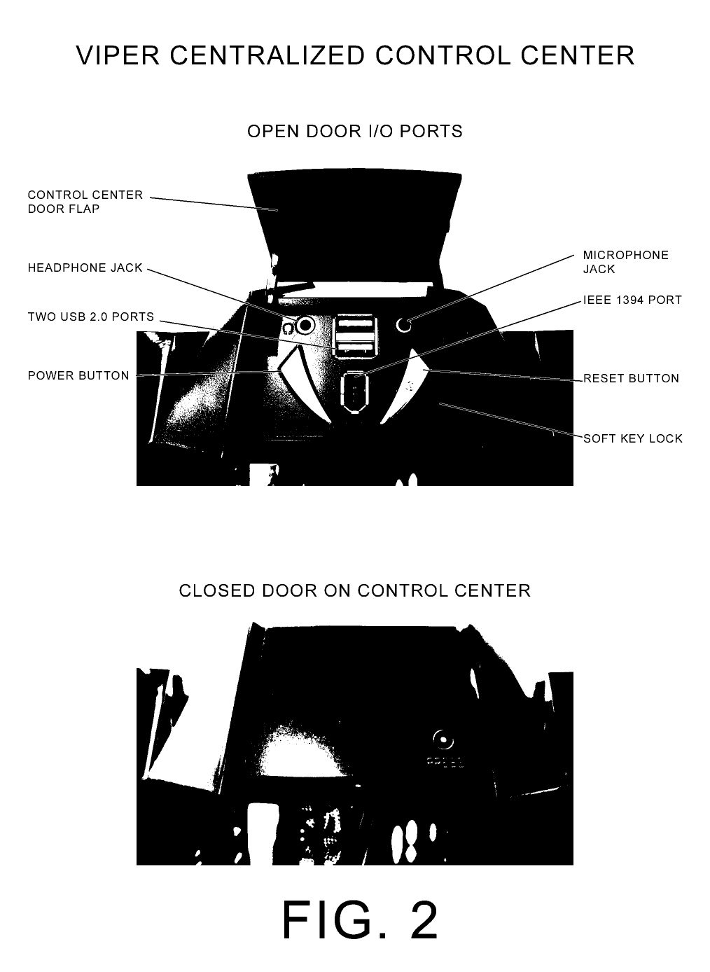

FIG. 3 illustrates the first time ever Magnetically Closed Drive Bay Door which allows the door to be softly held tight whenever in transport.

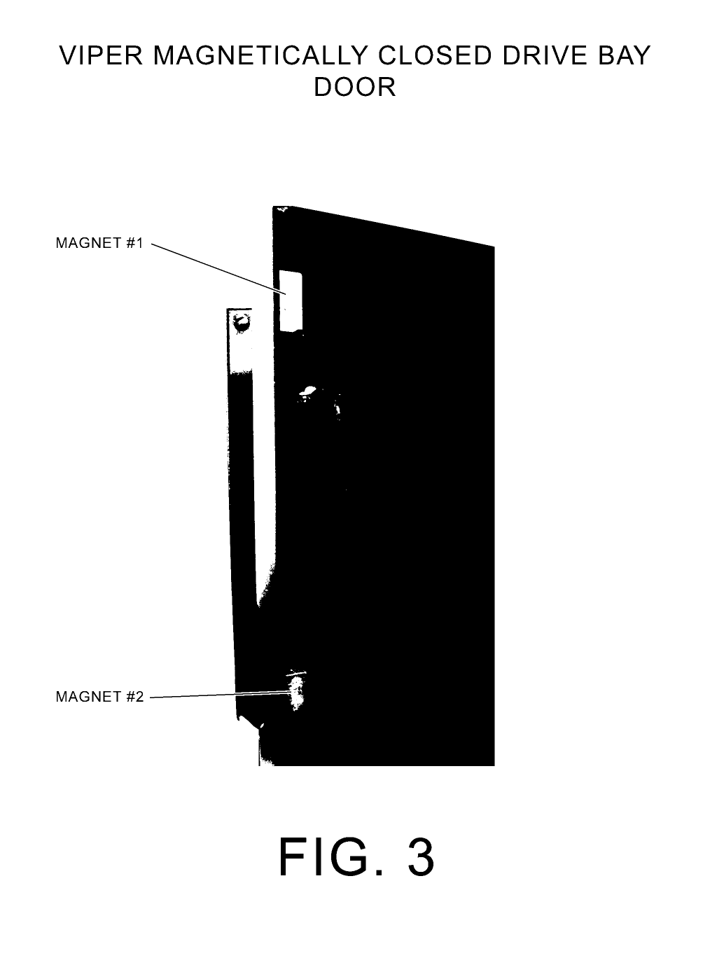

FIG. 4 shows the Dual Re-Inforced Handles that allow the end user to carry the VIPER when ever in transport.

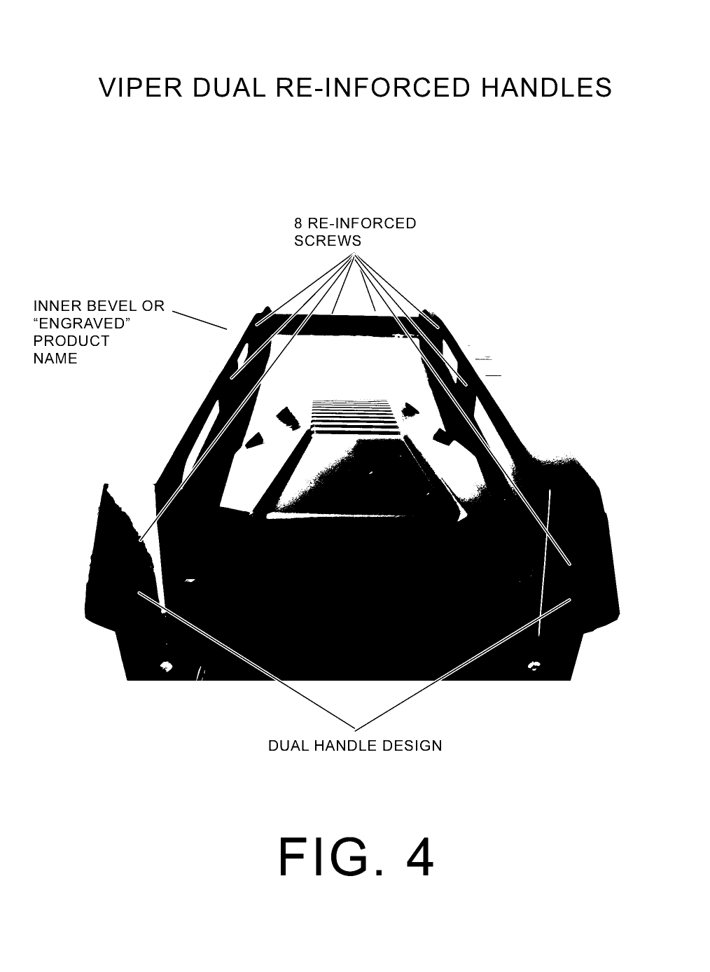

FIG. 5 illustrates the entire VIPER computer chassis in its entirety.

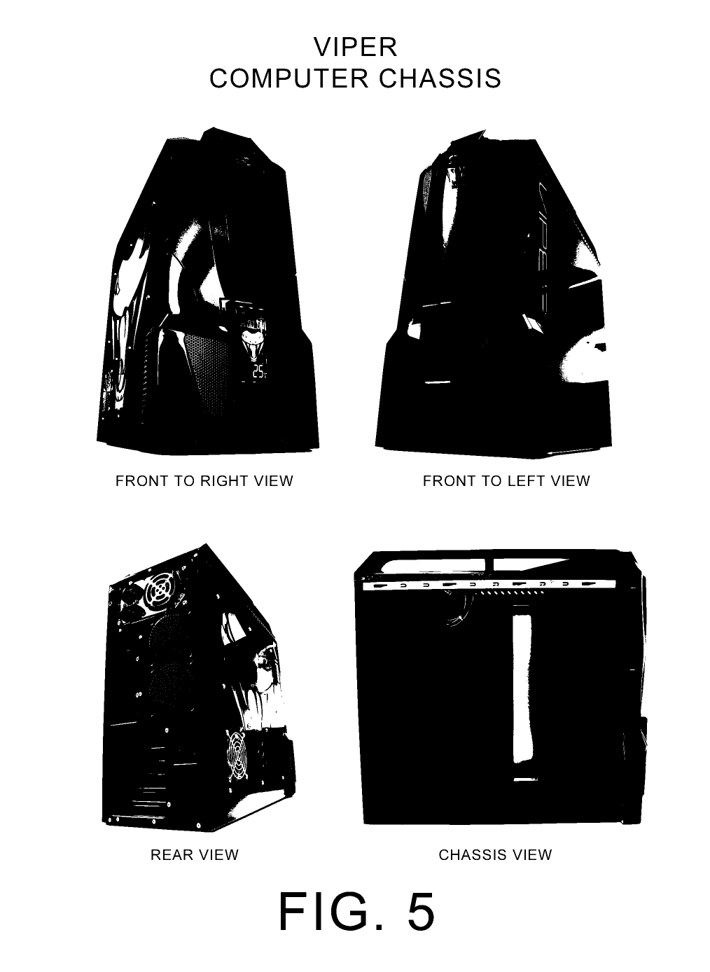

### DETAILED DESCRIPTION

Since its creation, VIPER has set the standard in what a computer case should be. This case demonstrates many great hard to find features such as: high gloss paint, LCD temperature display and total usage time built right into the case. MGE has took the time to create the technology used display a high resolution VIPER image embedded and programmed into the LCD display. The display itself does not only show a high resolution image of the emblem but also illustrates the “total usage time” which allows the end user to view the total time the computer system has been on for an “x” amount of hours. The LCD display also reads temperature ‘hot spots’ that can be mounted on several areas of the computer such as; processing unit—the central core of the computer, hard-drive unit—which stores the data the end user records into, or the over all system—which is the motherboard or main circuit board where everything is plugged into.

Other great features of the VIPER, is the first LED lighted VIPER emblem on the door. This particular piece made up of a single clear red acrylic plastic material that allows the luminescence to travel directly through the plastic VIPER emblem. Thus allowing a lighted VIPER logo mounted into the door. The piece is lighted by the use of LED light(s) that are mounted behind and side of the actual part within the door. VIPER is first to introduce a massive front panel air vent that spreads 165 mm in width, 120 mm in height—allowing for a full front ‘increased’ airflow that dramatically reduces the heat from mounted hard-drive bays, thus increasing the speed of the data search and data transfer rates. “Out of the Box” design was created to meet a demand in a more three dimensional look and feel throughout the front panel that spreads into the side panels. The VIPER's external chassis has been painted with a high gloss coat giving it an unparallel look and feel of unsurpassed quality. The internal chassis of the VIPER has also been painted to equal out the overall design of the VIPER. Next is the Centralized Control Center with is the housing of several great features: power button, reset button, dual USB 2.0 ports, a single firewire port, speaker and mic connections. This allows the end user ease of use when plugging in their external electronic devices such as mouse, keyboard, headphones, and/or mic to name a few.

VIPER also introduces a unique method of full drive bay cooling by having a 70mm circular cut on top of the panel, plus giving it top vents built into the same housing of the Centralized Control Center. Heat travels upward and the VIPER's airport “transfers this heat from the 5.25” drive bay on through the top panel vents thus enabling a stable, more reliable, and increased system performance. VIPER is also first to introduce a UV (ultra violet) blue acrylic window that transfers ultra violet light throughout the entire acrylic window from a single or multiple ‘UV’ source. VIPER introduces dual top re-inforced steel handles that allow an even weight distribution when carrying the computer chassis, with the use of 8 screws for total re-inforcement and it also introduces the use of an “embedded” logo that has been cut into the handle giving it a total appeal to the overall computer chassis. VIPER is only case in its mid ATX class to come equipped with a 500 WATT rated power supply that has nylon netted sleeves around the exposed internal wires and offer Serial ATA (SATA) power connectors for SATA computer components. The last unique feature of the VIPER is the rear “static guard” that helps prevent rear end damage when mobile and conveniently addresses the need for cable management when plugging in the external power cable and various other cables belonging to the computer.

1. The VIPER LCD display digitally creates a high resolution image that is embedded and programmed for visibility, controllability, and can be animated. Its is the first and only LCD display that can take any image created and digitally insert it in which it may be displayed with various colors. The LCD display illustrates the total usage time that enables the end user to view the computer systems total time that it has been in use. The LCD also illustrates a temperature display of any given computer component within the computer system with the use of its sensor(s). The display has the ability to read hard-drive spinning which illustrates the hard-drives working condition. Other add-on ability includes a temperature alarm that will beep whenever the computer system temperature sensor records a 70 degree fahrenheit wherever it may be applied to. Such a feature will allow the end user time to make remedies according to the overheated component(s) thus aiding the end user to cool down the internal component and prolong the components life span.

2. The VIPER emblem or “logo” itself is trademarked under the MGE COMPANY which is LED lighted on the front door panel.

3. The Front panel is also designed to create an abundant flow of air thus giving each mounted hard-drive storage device the cooling it needs to maintain system stability, speed, and increased data search and retrieval performance. Front Panel Airflow Access spreads: 165 mm Width, 120 mm Height. The compute chassis itself is first to allow full frontal airflow.

4. ‘Out of the Box’ Design allows a more three dimensional look and feel throughout the front panel that spreads into the side panel.

5. Our new I/O Port Hub gives the end user a remote location of several needed computer ports while conveniently placing the power and reset buttons within this enclosure area called the Central Control Center. This particular part gives the end user the ability to use two USB 2.0 components, one IEEE 1394 component, as well as speaker and microphone ports for added convenience.

6. Top Panel Vents is specifically designed only for the sole purpose of its function to allow heat from the computer chassis drive bays to dissipate and flow through the top section of the top panel computer chassis, which then goes throughout the air vents. A 40 to 80 mm cut may be applied to facilitate a larger expense of cooling. Thus expanding the life expentency of the drive bay component, which also aides in the increased performance of the overall computer system.

7. The acrylic plastic of the side panel itself is ultra violet (UV) coated which allows it to transfer ultra violet light throughout the entire window of the computer chassis thus allowing light to be evenly distributed throughout the entire internal chassis.

8. Dual re-inforced steel handles are located on the top panel of the computer chassis that allow an even distribution of weight when picking up the computer chassis. It is re-inforced by the way of eight screws that maintain and handle the weight distribution. Each handle has a die cut name of the product which gives the overall aesthetic feel of the computer chassis a more complete design. An additional beveled aluminum alloy plate with the product's name imprinted within the material may be used alternatively to complete its aesthetic goal. The aluminum plate may be mounted by the use of 4 to 8 screws or rivots.

9. The trademarked VIPER name is utilized and painted in a high gloss format that expands from the front top end to the front bottom end on both sides of the side panels allowing for a more aggressive and highly stylized appeal to the end user.

10. The computer chassis itself allows for a full drive bay expandability throughout the entire internal chassis. This gives the end user full advantage of maximizing the computer chassis potential.

11. The computer chassis itself is hard color coated which is powdered paint sprayed on the chassis and then sent into a kelm oven which melts the powder into a liquid form and then binds the paint into the metal. The end result a tough and durable chassis that is 98% scratch resistant and yet offers a colorful result to the internal chassis of the computer system.

12. The VIPER's Power Supply is rated at 500 Watts of power that features nylon sleeve and SATA Power Conversion for SATA Harddrives. The nylon sleeves across the main set of wires increase overall cable management throughout the entire chassis.

13. The rear “Static Guard” enables the computer user to properly manage their cables when connecting or wiring the VIPER with its external components and/or power cable. This allows a for an easier management of system setup and protects the rear of the computer chassis whenever mobile.
